(19) United States
(12) Patent Application Publication
(10) Pub. No.: US 2005/0037578 A1
(43) Pub. Date: Feb. 17, 2005

(54) [METHOD FOR FORMING AN OXIDE/ NITRIDE/OXIDE STACKED LAYER]

(76) Inventors: Wei Wen Chen, Hsinchu (TW); Tzung-Ting Han, I-Ian (TW); Yun-Chi Yang, Hsinchu County (TW); Ling-Wuu Yang, Taichung (TW); Kuang-Chao Chen, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/604,764

(22) Filed: Aug. 14, 2003

(51) Int. Cl. H01L 21/336; H01L 21/76; H01L 21/31; H01L 21/469

(52) U.S. Cl. 438/261; 438/763

(57) ABSTRACT

A method for fabricating a silicon oxide/silicon nitride/silicon oxide stacked layer structure is described. A bottom oxide layer is formed over a substrate. A surface treatment is then performed on the first silicon oxide layer to form an interface layer over the bottom oxide layer. The surface treatment is conducted in a nitrogen ambient. Thereafter, a silicon nitride layer is formed over the interface layer, followed by forming an upper silicon oxide layer over the silicon nitride layer.

### BACKGROUND OF INVENTION

1. Field of Invention

The present invention relates to a fabrication method for an oxide/nitride/oxide (ONO) stacked layer. More particularly, the present invention relates to a fabrication method for a silicon oxide/silicon nitride/silicon oxide stacked layer where damage induced upon the silicon nitride layer due to electron injection and ejection is mitigated.

2. Description of Related Art

A typical flash memory device comprises a polysilicon gate and an oxide/nitride/oxide (ONO) stacked layer structure. The ONO stacked layer includes a bottom silicon oxide layer overlying the channel region. A silicon nitride layer serving as an electron trapping layer overlies the bottom silicon oxide layer and an upper silicon oxide layer overlies the silicon nitride layer. An ion implantation process is further performed on the substrate to form a source/drain region in the substrate adjacent to the two ends of the silicon nitride layer.

During the programming of the memory device, electrical charges are transferred from the substrate to the silicon nitride layer in the ONO stacked layer. Voltages are applied to the gate and the drain creating vertical and lateral electric fields which accelerate the electrons along the channel. As the electrons move along the channel, some electrons would gain sufficient energy to jump over the potential barrier of the bottom oxide layer to become trapped in the silicon nitride layer. Electrons are trapped near the drain region because the electric fields are the strongest near the drain. Reversing the potentials applied to the source and the drain will cause electrons to travel along the channel in the opposite direction and be injected into the silicon nitride layer near the source region.

However, subsequent to multiple times of the electron injection and ejection operation performed on the silicon nitride layer, damages may induce upon the silicon nitride layer. Consequently, current leakage may occur to adversely affect the reliability of the memory device.

### SUMMARY OF INVENTION

The present invention provides a fabrication method for an ONO structure layer, wherein a sturdy interface layer is formed between the silicon nitride layer and the bottom oxide layer to mitigate damages induced upon the silicon nitride layer due to electron injection and ejection.

The present invention further provides a fabrication method for a silicon nitride layer, wherein variation of the breakdown voltage of the memory device formed with the silicon nitride layer according to the present invention is smaller.

The present invention provides a fabrication method for a silicon oxide/silicon nitride/silicon oxide stacked layer. A silicon oxide layer is formed over a substrate surface. A surface treatment process is then performed on the first silicon oxide layer. The surface treatment process comprises an in-situ treatment with nitrogen gas. Subsequent to the surface treatment, an interface layer, which serves as a nucleation layer for the subsequently deposited silicon nitride layer, is formed over the silicon oxide layer.

In accordance to the present invention, a sturdy interface layer is formed between the bottom oxide layer 102 and the silicon nitride layer 106. The integrity of the silicon nitride layer 106 is maintained even after multiple times of the electron injection and ejection operation.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to 1C are schematic cross-sectional views, showing the manufacturing of a silicon oxide/silicon nitride/silicon oxide stacked layer structure according to one aspect of the present invention.

### DETAILED DESCRIPTION

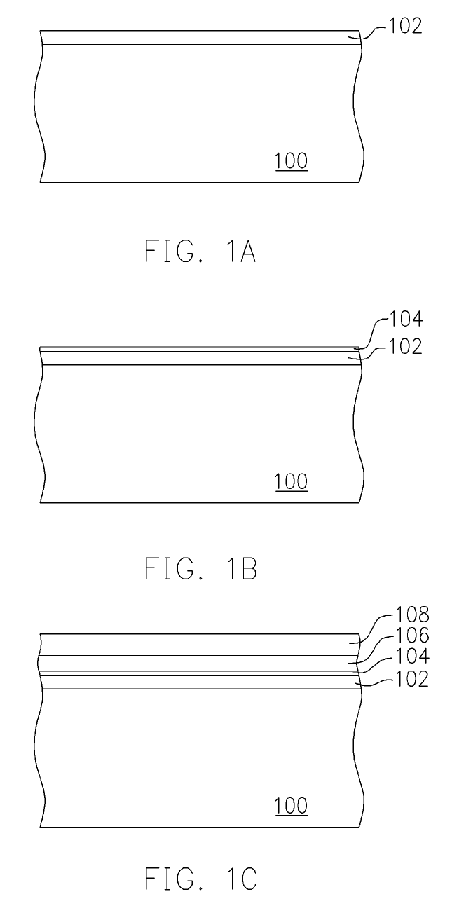

Referring to FIG. 1A, a substrate 100 is provided. The substrate 100 is, for example, a silicon substrate, which may include numerous devices formed thereon and therein. An oxide layer 102 is then formed on the substrate 100. The oxide layer 102 is formed by thermal oxidation or by deposition.

Referring to FIG. 1B, subsequent to the formation of the oxide layer 102, an in-situ treatment process is performed on the oxide layer 102. The treatment process comprises a surface treatment process performed in a nitrogen ambient on the oxide layer 102. The treatment process is conducted, for example, with ammonium (NH₃), under a pressure of about 10 torr to 80 torr, at a temperature of about 650 degrees Celsius to 800 degrees Celsius, preferably around 800 degrees Celsius for about 1 to 2 hours.

In another aspect of the present invention, the treatment process is accomplished through rapid thermal processing. The rapid thermal process is conducted at a temperature of about 650 degrees Celsius to about 1100 degrees Celsius for about 30 to 90 seconds. Subsequent to the surface treatment process, an interface layer 104 is formed on the surface of the oxide layer 102. The interface layer 104 is, for example, a silicon oxynitride (SiOₓN_{y}) layer. The interface layer 104 is about 20 angstroms thick.

Continuing to FIG. 1C, using the interface layer 104 as a seed layer, a silicon nitride layer 106 is formed. Thereafter, an oxide layer 108 is formed over the silicon nitride layer 106.

In accordance to the present invention, an interface layer 104 is formed between the silicon oxide layer 102 and the silicon nitride layer 106. Therefore, the quality and the integrity of the silicon nitride layer 106 are maintained even after multiple times of the electron injection and ejection.

Further, since the quality of the silicon nitride layer 106 is improved, the breakdown voltage of the memory device can be more consistent.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A fabrication method for a silicon oxide/silicon nitride/silicon oxide structure layer, comprising:
forming a first silicon oxide layer over a substrate;
forming an interface layer over the first silicon oxide layer;
forming a silicon nitride layer over the interface layer; and
forming a second silicon oxide layer over the silicon nitride layer.

2. The method of claim 1, wherein the interface layer is formed by performing a surface treatment process on the first silicon oxide layer in a nitrogen ambient.

3. The method of claim 1, wherein the interface layer is formed by exposing the first silicon oxide layer to ammonium.

4. The method of claim 1, wherein the interface layer is formed under a pressure of about 10 torr to about 80 torr.

5. The method of claim 1, wherein the interface layer is formed at a temperature of about 650 degrees to about 800 degrees Celsius for about 1 hour to 2 hour.

6. The method of claim 1, wherein the interface layer is formed at a temperature of about 650 degrees to about 1100 degrees for about 30 seconds to about 90 seconds in a nitrogen ambient.

7. The method of claim 1, wherein the interface layer is about 20 angstroms thick.

8. The method of claim 1, wherein the interface layer comprises silicon oxynitride.

9. The method of claim 1, wherein the interface layer serves as a seed layer for forming the silicon nitride layer.

10. A fabrication method for a silicon oxide/silicon nitride/silicon oxide structure layer, comprising:
forming a first silicon oxide layer over a substrate;
performing a surface treatment process over the silicon oxide layer to convert a surface of the silicon oxide layer to a thin silicon oxynitride layer;
forming a silicon nitride layer over the surface-treated silicon oxide layer; and
forming a second silicon oxide layer over the silicon nitride layer.

11. The method of claim 10, wherein the surface treatment process is conducted with ammonium.

12. The method of claim 10, wherein the surface treatment process is conducted at a temperature of about 650 degrees Celsius to about 800 degrees Celsius for about 1 to 2 hours.

13. The method of claim 10, wherein the surface treatment process is conducted at a temperature of about 650 degrees Celsius to about 1100 degrees Celsius for about 30 to 90 seconds.

14. The method of claim 10, wherein the surface treatment process is conducted under a pressure of about 10 torr to about 80 torr.

15. The method of claim 10, wherein the thin silicon oxynitride layer is about 20 angstroms thick.
